(19) United States
(12) Patent Application Publication
(10) Pub. No.: US 2022/0340414 A1
(43) Pub. Date: Oct. 27, 2022

(54) METHOD OF ASSEMBLING MOBILE MICRO-MACHINES AND A MOBILE MICRO-MACHINE

(71) Applicant: MAX-PLANCK-GESELLSCHAFT ZUR FÖRDERUNG DER WISSENSCHAFTEN E.V., München (DE)

(72) Inventors: Berk M. Yigit, Stuttgart (DE); Yunus Alapan, Stuttgart (DE); Onur Beker, Karabaglar/IZMIR (TR); Metin Stitti, Stuttgart (DE)

(21) Appl. No.: 17/762,715

(22) PCT Filed: Sep. 23, 2019
(86) PCT No.: PCT/EP2019/075564

§ 371 Date: Mar. 22, 2022

(51) Int. Cl. B81C 1/00; H02N 1/00; B81B 7/00

(52) U.S. Cl. CPC B81C 1/00007; H02N 1/004; B81B 7/0003; B81B 2201/038

(57) ABSTRACT

The invention relates to a method of assembling mobile micro-machines comprising a main body and at least one actuating element, wherein the method comprises the steps of defining a 3D-shape of elements of the mobile micro-machines, the elements comprising components such as the main body and/or the at least one actuating element; fabricating said elements, said step of fabrication comprising at least the fabrication of the main body, the main body comprising one or more edges; and assembling said mobile micro-machines by applying an external electric field, wherein said external electric field forms electric field gradients at said one or more edges and wherein said gradients attract said actuating element so that the main body and the at least one actuating element self-assemble into a micro-machine at said one or more edges. The invention further relates to a mobile micro-machine.

The invention relates to a method of assembling mobile micro-machines comprising a main body and at least one actuating element. The invention further relates to a mobile micro-machine.

Mobile micro-machines offer a significant potential not only for probing and manipulating the microscopic world but also for creating functional order and assemblies at the micro- and meso-scale. A micro-machine is ideally composed of multiple parts, materials or chemistries that address different functions such as actuation, sensing, transport and delivery. Functional modes and performance are dictated by how these components are organized and interact within the machine.

Current micro-machines are generally fabricated as monolithic units due to challenges in the directed assembly of functional components in a spatially controlled manner. Micro-machines made of modular sub-units would enable reconfigurable and multiple functionalities and more complex modes of motion by controlling the relative configuration of the components.

One prominent approach to achieve organization of microscopic parts into a specific structure is self-assembly, where physical interactions between the parts spontaneously drive their assembly. Energy supplied by external fields or chemical fuels can power the activity of the micro-machines while simultaneously directing the physical interactions for self-assembly of sub-units. For example, magnetic particles interacting under rotating magnetic fields assemble into chains or wheels that are capable of locomotion near solid surfaces. Light-activated micro-swimmers assemble into living crystals and self-rotating gears via diffusiophoretic interactions arising from consumption of chemicals (e.g. hydrogen peroxide).

Designing more complex modular micro-machines comprising diverse parts using self-assembly requires an understanding of the operational dynamics between the parts and of the engineering of the assembly pathways through physical interactions. Physical interactions can be programmed into individual parts by taking advantage of shape and material specific force responses under external fields. Examples include colloidal assembly of high-performance spatially structured composite microstructures with virtual electric and magnetic molds.

Although these approaches demonstrated programmable structural assemblies, there is a significant interest to extend these approaches to mobile micro-machine assemblies. In this perspective directed assembly pathways of active colloidal clusters using externally actuated and self-propelled particles are actively investigated, but fully programmable control over the design of self-assembled micro-machines remains a significant challenge.

It is therefore an object of the invention to provide a micro-machine and a method for assembling mobile micro-machines, which can overcome the above mentioned challenges.

This object is satisfied by the subject matter of independent claim 1.

In particular, the method according to the invention comprises the steps of defining a 3D-shape of elements of the mobile micro-machines, the elements comprising components such as the main body and/or the at least one actuating element; fabricating said elements, said step of fabrication comprising at least the fabrication of the main body, the main body comprising one or more edges; providing a solution in which the micro-machine can be placed; placing said fabricated main body of the mobile micro-machines into said solution; providing the at least one actuating element in said solution; and assembling said mobile micro-machines by applying an external electric field, wherein said external electric field forms electric field gradients at said one or more edges and wherein said gradients attract said actuating element so that the main body and the at least one actuating element self-assemble into a micro-machine at said one or more edges.

In other words, at least the main body of the micro-machine is designed and then fabricated. During the step of designing the application of the micro-machine is taken into consideration and the design thereof can then be tailored to the specific application. For example, the micro-machine could be designed as a medical robot and has to be able to be moved along a blood vessel with the flow of blood or through the esophagus by swallowing e.g. in a solution of water. In other designs the micro-machines can be used to investigate plumbing within a house and have to be designed such that they are capable of being moved through the piping installations present within a house. In another design, the micro-machines can be used to biochemically or mechanically probe and manipulate cells and other agents in in vitro cellular assays, microfluidic systems, and organ-on-a-chip systerns. Therefore, the actuating element can also be designed as a sensing or a cargo, i.e. for example a drug, carrying element in order to also comprise other functions except from moving the micro-machine.

In this connection it should be noted that the one or more actuating elements are moveable relative to the main body thereby one can move the main body on moving the actuating elements.

In some embodiments the at least one actuating element is designed and fabricated as well while in other embodiments one or more actuating elements from commercially available sources are used. In general, the main body can comprise one or more actuating elements depending, for example, on the specific design of the main body or the specific application of the assembled micro-machine.

After fabricating the designed elements of the micro-machine, all elements are placed in a solution and an external electric field is applied to said elements. Since the main body comprises one or more edges the electric field forms electric field gradients at said edges, which attract the one or more actuating elements. This leads to a self-assembly of the different components into a micro-machine.

Specifically, advantage of dielectrophoretic (DEP) forces for encoded assembly of functional components is taken by precisely controlling the distribution of the electric field gradients generated around the main body through modulation of its designed three-dimensional (3D) geometry. The resultant interactions with the actuating elements are site-selective and directional. Mobile micro-machines, powered by actuating elements such as multiple magnetic and self-propelled actuators, perform reconfigurable modes of locomotion depending on the spatial organization of the actuators, which can be reconfigured with field parameters. Furthermore, it has been shown that the mechanical coupling strength between the actuating elements, i.e. the actuators, and the main body can be tuned by DEP forces, which gives control over rotational degrees of freedom ranging from free rotation to rigid body rotation. Designing directed assembly and controlled operational dynamics between functional components via shape-encoded DEP forces enables a rich design space for development of functional micro-machines and mobile microrobots performing complex tasks.

In an embodiment of the invention the main body comprises one or more body parts. Thus, it is possible to design and fabricate several types of body parts, which can self-assemble in order to form one “regular” or also one bigger micro-machine, meaning that the body parts can be assembled to a main body, which then assembles with other main bodies to a bigger micro-machine. That is to say that the exact design of the main body can depend on the specific application of the micro-machine or even on the possibilities of fabrication. Hence, several types of designs for the main body comprising one or more body parts are possible.

According to another embodiment the main body is fabricated via 2D and/or 3D printing. A printing process is often a convenient method for fabricating rather small components. It is comparatively cheap but yet precise enough to fabricate components with a size in the range of several micrometers. The main body can also be fabricated with top-down and bottom-up microfabrication techniques including but not limited to: photolithography, physical vapour deposition (sputtering, glancing angle deposition, etc.), template assisted electrodeposition, MEMS processes, colloidal synthesis (growth of particles), self-assembly, DNA self-assembly and a combination thereof.

According to still another embodiment of the invention the main body comprises at least one cavity for at least one actuating element. Hence, it is possible that one cavity for each actuating element is provided, but also main bodies comprising one cavity for more than one actuating element are feasible.

In this connection it is also possible that the at least one cavity forms a respective one or more of said one or more edges. This means that the one or more edges can be formed, for example, at the boundaries of the at least one cavity. This way, the electric field gradients are formed such that they attract the at least one actuating element into said cavity in order to trap it in the cavity.

In this connection it should be noted that the actuating element may further be configured as a sensing element and/or as a cargo carrying element. In this way the actuating element, e.g. the wheel of such a mobile micro machine can also be doped with e.g. a cargo and/or a further material which permits the mobile micro machine to be tracked at it position of use, e.g. using magnetic imaging, x-ray imaging, IR or Ultrasound etc.

Similarly the main body may also be further configured as a sensing element and/or as a cargo carrying element. In a particularly beneficial design, the main body may carry a first component of a two-component material and the actuating element may carry a second component of a two-component material, with at least one of the main body and the actuating element then being configured to release the respective component either in the environment of the target site via an external stimulus or due to e.g. a chemical reaction induced at the target site.

According to another embodiment the main body is fabricated of a resin, especially of an IP-S resin, biological materials or drug loaded materials. The materials can be chosen according to the application of the micro-machine and/or according to the fabrication process used for fabricating the main body. A plurality of different materials is possible. Furthermore, most materials are electrically polarizable, which generalizes the applicability of the presented assembly methodology to synthetic (polymers, hydrogels, metals, ceramics, liquid droplets, and hybrids of the aforementioned) as well as biological matter (animal cells, bacteria, algae, etc.). This capability can allow site-specific integration of various actuator, sensor and cargo delivery units that have different material compositions that can be fabricated through separate processes. The main body can also be fabricated of soft materials such as elastomeric polymers, which can allow deformations of the main body.

In still another embodiment a shape of the actuating element is also defined during said step of defining a 3D-shape of elements of the micro-machines. Thus, as mentioned above, the actuating element can also be designed according to the application and/or according to the design of its corresponding main body. This makes the method even more accurate and flexible since basically every component of the micro-machine can be designed as needed in dependence on the specific task.

It this connection it is also possible that the actuating element is fabricated via 2D and/or 3D-printing during said step of fabricating said elements. Thus, the same fabrication process as the one used for the fabrication of the main body can be used to fabricate the actuating element in order to ensure an easy and accessible way to fabricate all necessary components. In this connection it is noted that in general it is also possible to choose a different fabrication process for the actuating element as the one used for the main body if there are reasons to do so. The actuating elements can also be fabricated with top-down and bottom-up microfabrication techniques and a combination thereof: photolithography, physical vapour deposition (sputtering, glancing angle deposition, etc.), template assisted electro-deposition, MEMS processes, colloidal synthesis (growth of particles with different materials), self-assembly, DNA self-assembly, etc. The actuating elements can also be unicellular and multicellular biological organisms such as bacteria, microalgae, eukaryotic cells (spermatozoa, human cells, animal cells, single celled organisms), paramecium, volvox or the like. Furthermore, a body of the actuating element can be made of stiff as well as soft materials, which can enable deformations of the actuating element.

According to another embodiment of the invention the actuating element comprises one of a spherical shape, a cylindrical shape, an oval shape, a rectangular shape, a square shape, a polygonal shape and a triangular shape. Thus, when choosing a spherical or cylindrical shape the actuating element can act as a “wheel”, which rotates when it is driven, i.e. for example when it is exposed to a magnetic field. Since the micro-machine is also be placed in a solution or the like, other shapes for the actuating element are possible depending on the design of the main body and/or the precise application of the micro-machine. Other shapes can be utilized for actuating elements regarding desired functionalities such as helical actuators, which can swim when it is driven, i.e. for example when it is driven with a rotating magnetic field, or gear like shapes, which can be utilized for transmitting torque on the main body. The shape of the actuator elements can be deformable, when it is made of a soft material, or the design of the actuating elements possess parts that are connected by various linkages and hinges. For example, a soft and slender actuating element, which has a magnetic coating, can swim by means of deforming its body when driven with an oscillating magnetic field.

In another embodiment the actuating element comprises magnetic particles. For example, the actuating element can be coated with magnetic particles. Another example would be that instead of coating the magnetic particles, they can be embedded into the actuating elements during said step of fabricating, i.e. for example printing, said actuating elements. When using magnetic particles for the actuating element, it is possible to gain a better control of the movement of the actuating element and thus also of the movement of the micro-machine as a whole. Hence, it is possible to move the actuating element, or even the whole micro-machine, in a specific direction by applying a magnetic field to the micro-machine to which the magnetic particles react.

In this connection it is noted that it is also possible that the actuating element is at least partially coated with magnetic particles. Thus, the actuating element can comprise magnetic particles of two or more different materials. An example could be an actuating element with a surface, which is partially coated with one material while the rest of the surface is coated with another material, e.g. half and half. Since different materials react differently to external electric or magnetic fields, it can be advantageous to coat an element with different materials in order to gain control over the direction in which the element is moving when applying different electric or magnetic fields. This means that it can be possible to actively change the direction of movement of the actuating element.

In another embodiment the actuating element comprises a dielectric (electrically insulating) and an electrically conductive side. For example, a dielectric particle (e.g. silica) can be partially coated with a gold layer. Under an alternating electric field such actuating elements can propel themselves in random directions. Such actuating elements can assemble with the main body in prescribed directions at provided edges. The micro-machine that is formed upon such assembly is driven by the force exerted by the actuating elements to the main body in the direction of their propulsion.

According to another embodiment the particles have a size in the range of 0.01 to 1000 μm. This way the particles are small enough to be coated or embedded on or in the actuating elements.

According to another embodiment of the invention a field strength of the electric field lies in the range of 0.01 to 2*10⁹ V/m, preferably in the range of 1 to 2*10⁷ V/m. Since the electric field strength not only depends on the voltage but also on the distance between the electrodes, it is noted that said distance can range from 0.1 μm to 100 mm, especially from 10 μm to 500 μm. Furthermore, it is noted that for larger machines smaller field strengths will be required, while for smaller machines larger field strengths can be used. Thus, the appropriate filed strength has to be chosen according to the size of the assembled micro-machine. The field strength can either be increased by increasing the applied voltage, by decreasing the distance between the electrodes or by doing both.

It is another embodiment of the invention that the electric field comprises alternating electric fields between two plates, which is simply a typical and rather easy way of applying electric fields.

According to an embodiment of the invention the solution comprises deionized water. Depending on the materials used for the main body and the actuating element the solution can further comprise other ingredients. Deionized water is one of the most convenient solutions which can be chosen. Also, other media such as silicone oil and Dimethyl sulfoxide can be used.

In this connection it is noted that according to another embodiment the solution comprises a detergent. A typical example for such a solution is the solution TWEEN 20 from SIGMA ALDRICH, which is commercially available. A typical range for a detergent to water ratio can lie between 0 and 5% (v/v), preferably between 0.05 and 0.5% (v/v), especially 0.1% (v/v). Also other detergents are possible.

According to another embodiment of the invention the method further comprises the step of applying a magnetic field at the assembled micro-machines to move the at least one actuating element in a pre-defined direction in accordance with the magnetic field applied. In this connection it can be helpful when the actuating elements comprise the magnetic particles introduced above. Such an embodiment can make it easier to move the element in a precise pre-defined direction. It is also possible to use actuating elements which are completely made out of a magnetic material in order to be able to actively control them by applying said magnetic field.

According to still another embodiment of the invention two or more actuating elements are provided, wherein the main body comprises one or more edges for each actuating element so that each actuating element assembles at the respective one or more edge associated with said actuating element. Thus, the micro-machine can be assembled in the form of a “vehicle” with several “wheels”, which are incorporated by the actuating elements since every element assembles at its own edge. Said one or more edges for each actuating element may form a respective cavity associated with said actuating element. Thus, the micro-machine can be assembled in the form of a “vehicle” with several “wheels”, which are incorporated by the actuating elements since every element assembles at its own cavity. The association of actuating elements with specific cavities can be controlled by the size of the cavities. For example, actuating elements will not attach to specific cavities on the main body, if these cavities have dimensions that are smaller than the aforenoted actuating element. Also, instead of cavities, protruding shapes can be utilized to change the electric field gradient and can be used to control the association of several body parts. For example, a protruding shape can repel dielectric portions of actuating bodies of similar sizes, but can attract portions of actuating bodies made of a conductive material such as a metal coating.

In another embodiment the main body can comprise cavities and protruding edges, forming high or low electric field regions. Some actuators, e.g. self-propelling partially gold coated dielectric particles, can change their assembly position (reconfigure) depending on the applied alternating electric field frequency. Since the actuators would exert force to the main body from the assembly sites, locomotion type can be switched from linear motion to rotational motion or a combination thereof on-demand by changing the electric field frequency.

Another example would be the construction of a bigger micro-machine which comprises a main body with several body parts, where each body part comprises several cavities for each one actuating element. For some application bigger micro-machines may be needed. With the method according to the invention it is also possible to let the different parts of the micro-machine self-assemble to a bigger micro-machine, which can attract a plurality of actuating elements. Thus, there are no limitations in the design and/or size of the micro-machine.

According to another embodiment two or more actuating elements are provided for at least one of the cavities. That is to say that each cavity comprises several actuating elements which are able to collectively actuate the main body and thus the micro-machine as a whole.

According to a further aspect the present invention also relates to a mobile micro-machine comprising a main body and at least one actuating element optionally obtained by means of a method in accordance with one of the preceding claims, said at least one actuating element being arranged at one or more edges of said main body, said at least one actuating element having a size, such as a diameter, a width, a height and/or a length respectively selected in the range of 0.01 to 250 μm, in particular 1 to 100 μm, especially 5 to 80 μm and said main body having a height, width and/or length respectively selected in the range of 1 to 2000 μm, in particular 20 to 800 μm, especially in the range of 50 to 400 μm. In practice, there are no limitations on the size of particles, if sufficiently strong electric field strengths can be generated to drive the assembly.

Two or more actuating elements may be arranged at said main body. In this way a mobile micro-machine with e.g. two, three or four wheels can be made available.

Said one or more edges may form a respective cavity at which said one or more actuating element assembles, said cavities optionally having a size, such as a diameter, a width, a height and/or a length respectively, selected in the range of 31 to 201 μm, especially 41 to 81 μm. In this way the one or more actuating elements, e.g. wheels, can be arranged within a respective cut-out made available for the actuating element at the main body.

Said one or more edges may form a respective track over which one or more actuating element moves. In this way, actuating elements can move over the main body while their path is guided by the said tracks. This can be used to move actuating elements in any horizontal and vertical directions. Said capability may provide means to build micropumps arrays that can pump the solution by motion of its actuating elements about the main body. In another embodiment aforementioned capability may be used to build digital circuits to move cells and micro-machines in desired directions. In another embodiment actuating elements assembled on main body can serve as mechanical switches, linear and rotary bearing, and clutches.

Furthermore, the shape-directed assembly methodology can be extended to magnetophoresis. i.e. a motion of magnetizable particles in a non-uniform magnetic field, owing to its similarity to DEP. Instead, non-magnetic components can interact and assemble magnetically via the principle of magnetic holes if a magnetizable media is used (ferrofluids and paramagnetic fluids). A shape-directed magnetophoretic assembly can be further enriched using 3D time-varying magnetic fields.

Thus, with the method according to the invention it is possible to design and assemble different types and sizes of micro-machines. The exact design can then be chosen according to the application of the assembled micro-machine.

The invention as well as background information regarding the invention will be described in detail by means of the embodiments and with reference to the drawings, which show:

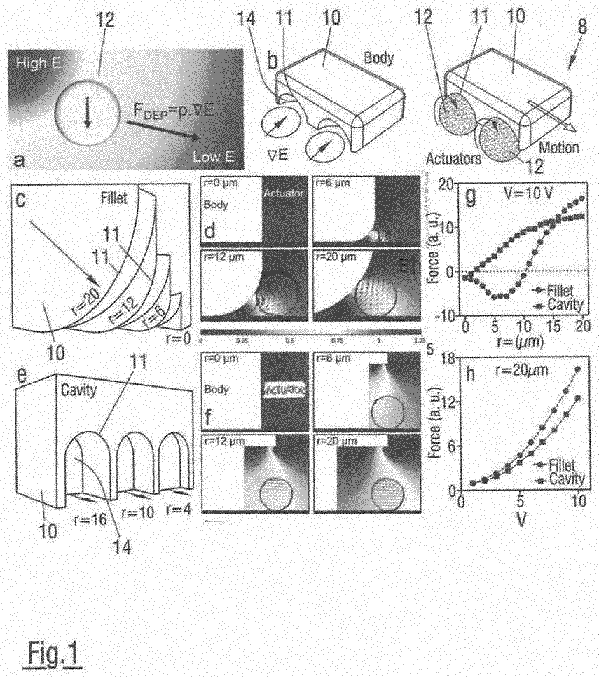

FIG. 1: a spatial encoding of dielectrophoretic attraction sites when modulating a 3D shape;

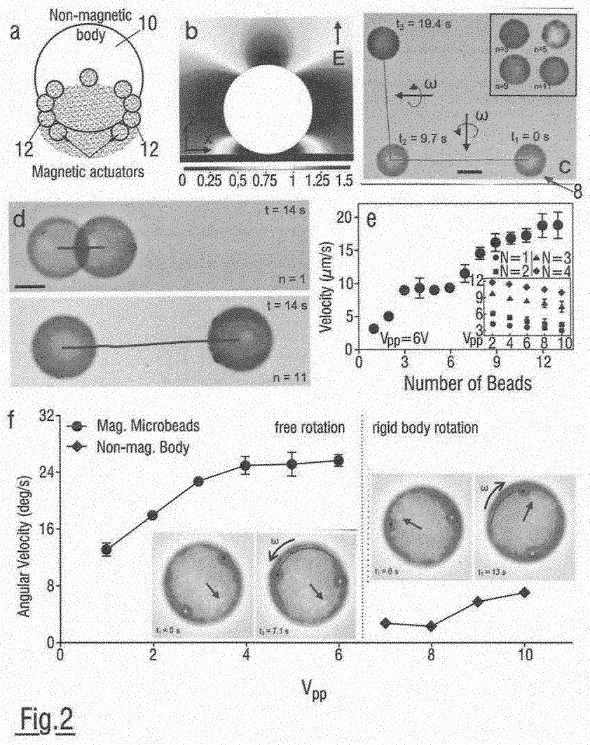

FIG. 2: a reversible assembly of magnetic actuating elements with a non-magnetic main body using DEP forces;

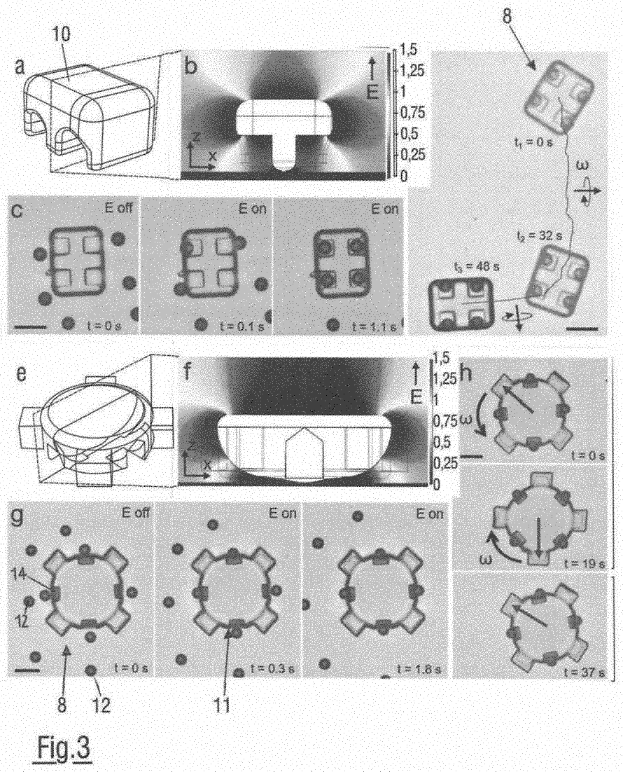

FIG. 3: a shape-encoded assembly of magnetic actuating elements to a 3D-nanoprinted non-magnetic main body;

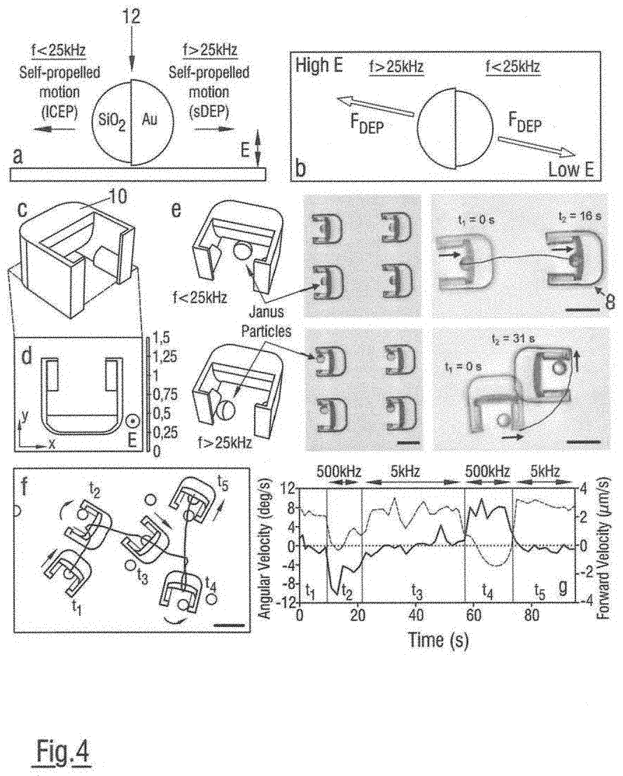

FIG. 4: a shape-encoded reconfigurable assembly of micro-machines with self-propelled actuating elements for frequency-tunable locomotion;

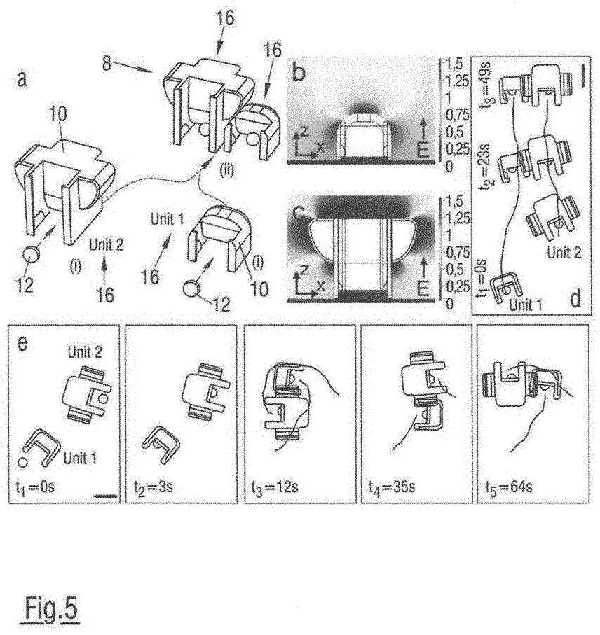

FIG. 5: a hierarchical assembly of multiple micro-machines via shape-encoded DEP interactions;

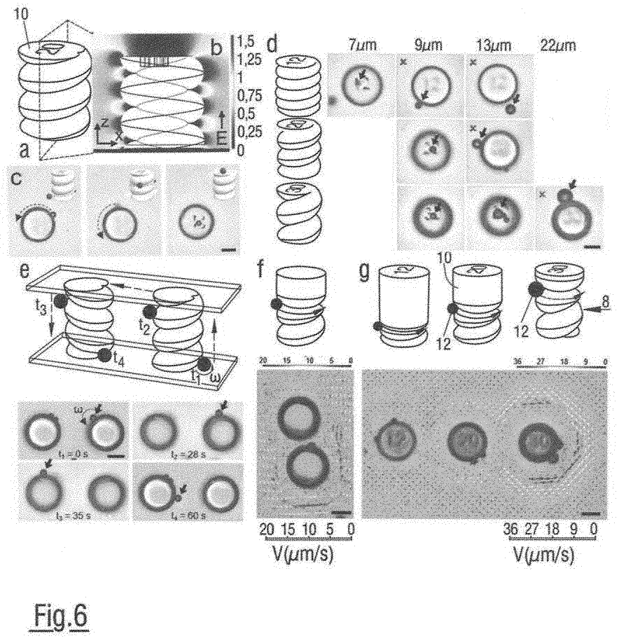

FIG. 6: a 3D manipulation of actuating elements and an assembly of micro-machines;

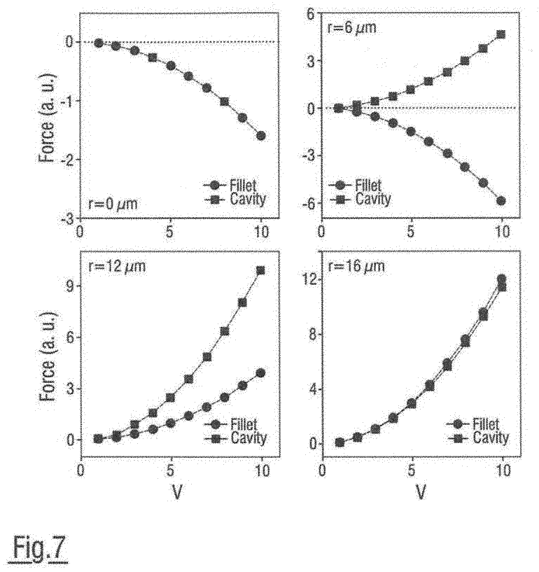

FIG. 7: the effect of the surface profile and the applied electric field amplitude on the DEP forces on a spherical particle;

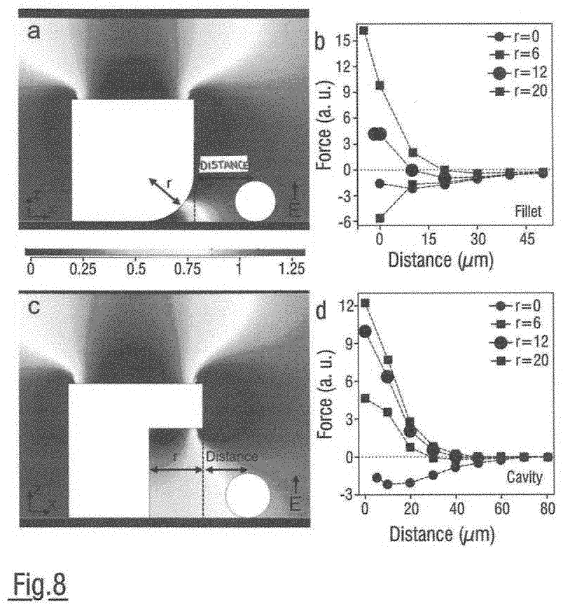

FIG. 8: the range of DEP forces on a spherical particle induced by different surface profiles;

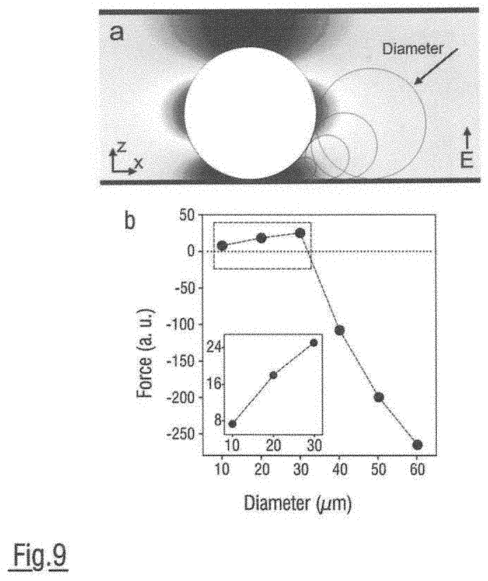

FIG. 9: the magnitude and direction of the DEP force between two spherical bodies in dependence on their relative sizes;

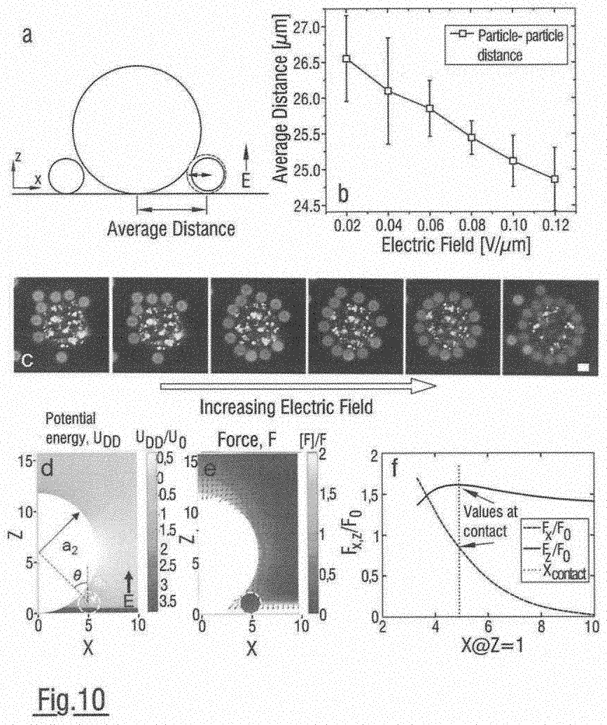

FIG. 10: the characterization of the average distance between central and satellite particles under electric fields;

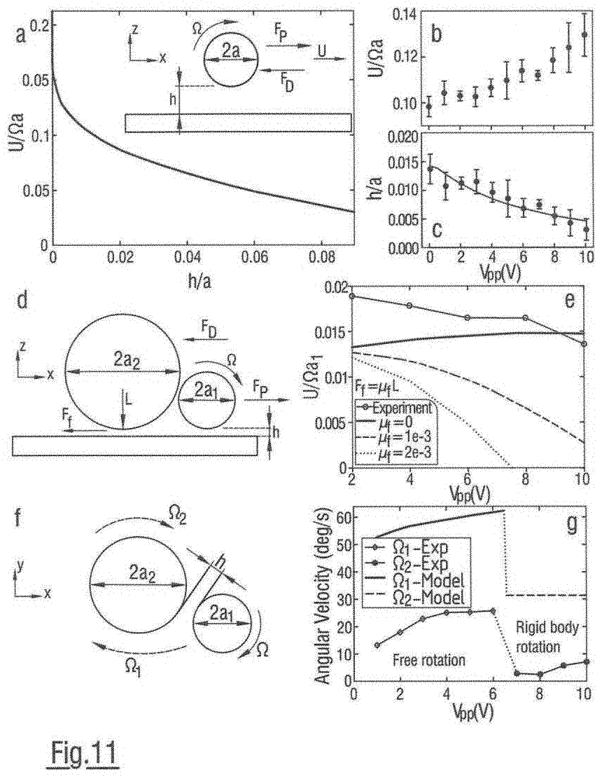

FIG. 11: the coupling between micro-components in translational and rotational micro-machines;

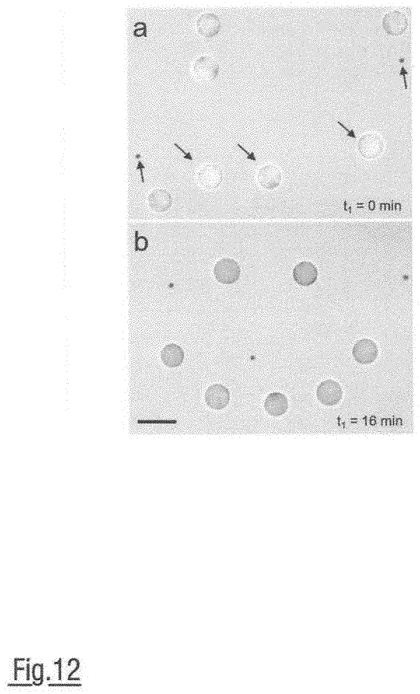

FIG. 12: a pick-and-place manipulation of non-magnetic objects by on-demand and reversible assembly with mobile magnetic micro-actuators;

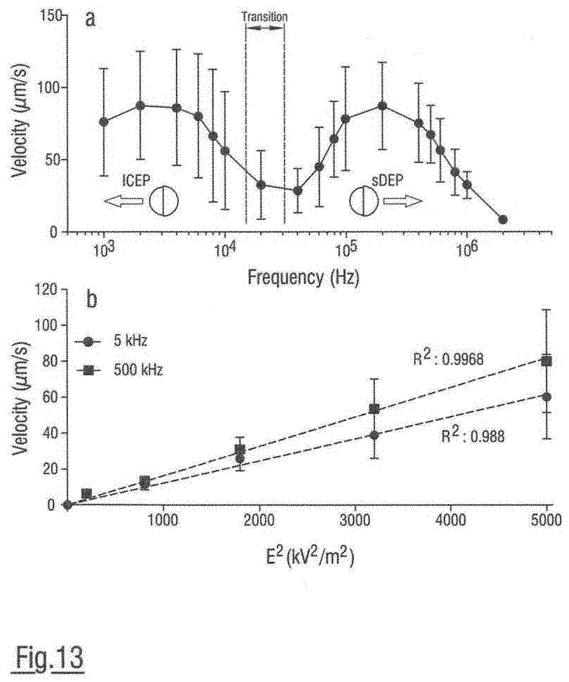

FIG. 13: the frequency-dependent mobility of Janus micro-particles;

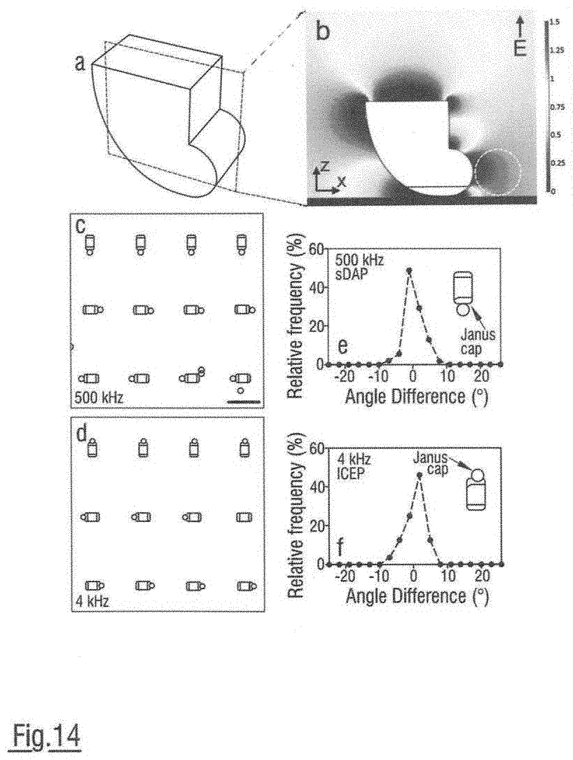

FIG. 14: a parallel and reconfigurable assembly of Janus particles to 3D-printed microstructures;

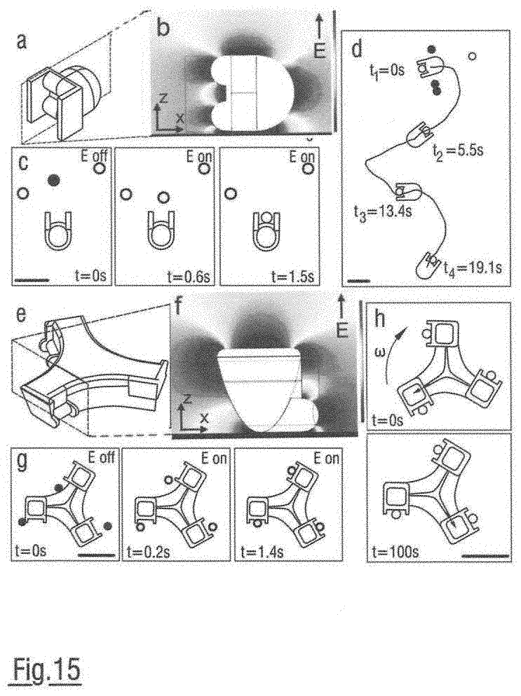

FIG. 15: a shape-encoded assembly of self-propelled micro-actuators to a 3D-nanoprinted body at high frequencies;

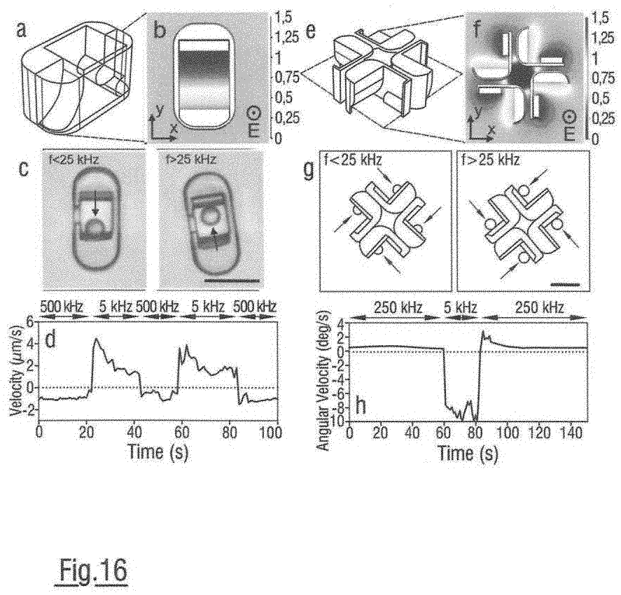

FIG. 16: a frequency-tunable bidirectional reconfiguration of mobile micro-machines;

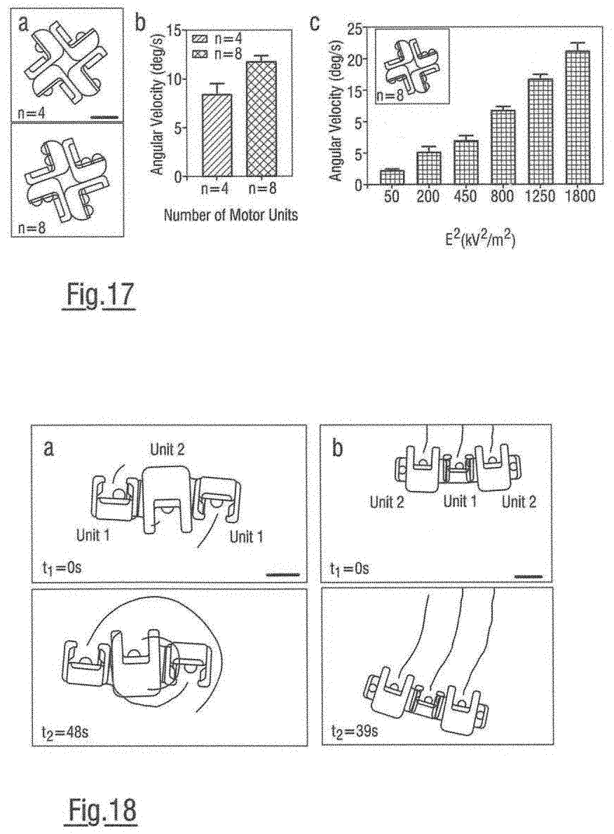

FIG. 17: a quantification of a micro-rotor performance;

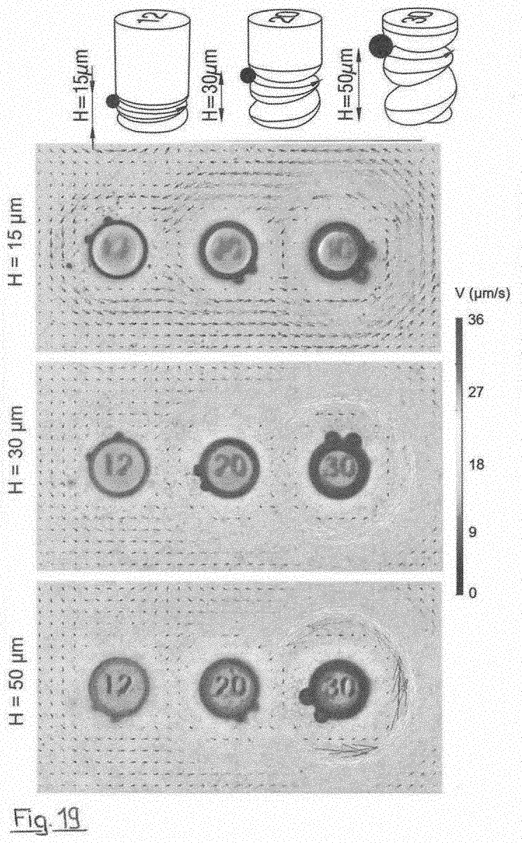

FIG. 18: a hierarchical assembly of multiple micro-machines;

FIG. 19: a flow generation with 3D micro-pump arrays; and

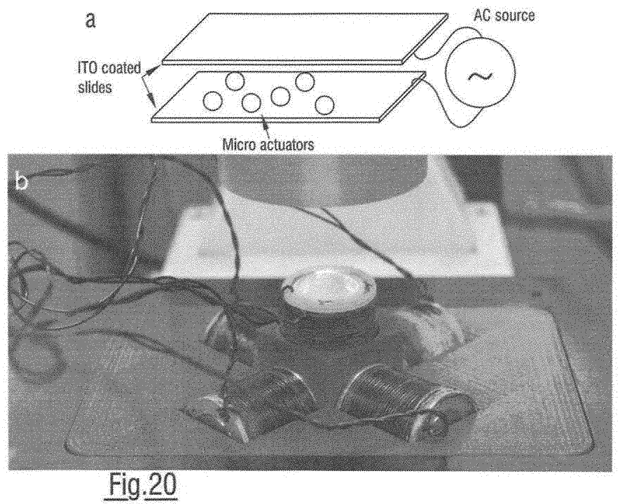

FIG. 20: an experimental setup.

In the following, first a short overview of what is shown in FIGS. 1 to 20 is given, which is then followed by a detailed explanation of the different embodiments of the invention as well as some background information that helps in understanding the method according to the invention.

FIG. 1(a) shows a negatively polarized actuating element 12 with a lower relative permittivity than the medium (≥ₚ<εₘ), which experiences a dielectrophoretic (DEP) force towards lower field magnitudes under a non-uniform external electric field E. FIG. 1(b) shows how DEP forces can be exploited for an encoded assembly of functional components by controlling local electric field gradients ∇E generated around a main body 10 through modulating its geometry such that the two actuating elements 12 are attracted towards the main body 10 to form an assembled micro-machine 8. The actuating elements are moveable relative to the main body. In FIGS. 1(c) and 1(e) one can see different 3D surface profiles (fillet or cavity) of a solid main body 10 with a lower relative permittivity than the medium (ε_{b}<εₘ) while altering an electric field strength E around the main body 10. FIGS. 1(d) and 1(f) show the creation of local gradients ∇E around the surface profiles of the main bodies 10 depending on a feature dimension r. Arrows represent electric field gradients ∇E imposed over the circular region representing a micro-actuating element 12 (10 μm diameter), which is located at the point of maximum force. The bar indicates the normalized electric field strength (E/E₀)². Negatively polarized smaller actuators 12 experience a DEP force towards (F>0) or away (F<0) from the indent due to the field gradient ∇E around the surface profile. FIGS. 1(g) and (h) show how the magnitude and direction of the DEP force depend on the profile type and feature size, as well as the applied voltage.

FIGS 1a and b thus show how a method of assembling mobile micro-machines 8 comprising the main body 10 and at least one actuating element 12 can take place. As will be explained in the following a 3D-shape of the main body 10 and optionally of the actuating element 12, i.e. of the elements of the mobile micro-machines 8 are defined in accordance with their specific application.

The respective elements are fabricated, e.g. using 2D or 3D printing processes, such that the main body 10 comprises one or more edges 11 to which the actuating elements 12 can be attracted. The edges 11 may form part of a respective cavity 14 into which the actuating elements 12 are attracted.

For example, the main body 10 can be 3D nanoprinted on a (coated) glass surface using a commercially available printer. Regarding the main body 10 shown in FIG. 1, it comprises an essentially rectangular main body 10 with two cavities 14, which cavities form edges 11 at their respective boundaries. Thus, the main body 10 can be printed as one piece and therefore comprises only one body part 16. In other examples, it can also be possible to design and fabricate a main body 10, which comprises more than one body part 16, which assemble to one single main body 10.

Thus, in the example described in FIG. 1 a main body 10 with two cavities 14 was selected and designed. The main body 10 can for example be nanoprinted from IP-S photoresist on an indium-tin-oxide (ITO) coated glass using a commercially available two-photon lithography system (Photonic Professional GT 3D printer, Nanoscribe GmbH, Eggenstein-Leopolds-hafen, Germany). Other materials, which can be used to fabricate the main body are for example polymers, hydrogels, metals, ceramics and liquid droplets.

In another example superparamagnetic polystyrene micro-particles with 10 μm diameter and embedded iron oxide nanoparticles (Product number: 41110, Sigma Aldrich, St Louis, Mo.) were used as magnetic actuators 12. Non-magnetic polyethylene microspheres of ˜60 μm diameter (Product number: UVPMS-BG-1.00 53-63 um-10 g, Cospheric, Santa Barbara, Calif.) were used as the robot body 10.

All experiments were performed in a 0.1% (v/v)Tween 20 solution (Sigma Aldrich, St Louis, Mo.) in deionized (DI) water to prevent any non-specific aggregations.

When using a printer for fabricating the main body 10, basically every shape can be fabricated. Thus, the exact design of the main body 10 with its respective edges 11—and possibly cavities 14—can be designed beforehand and can then be printed quite easily. Depending on the exact design the whole main body 10 can be printed in one step or it can consist of different body parts 16, which are printed separately and then assembled with each other in a second step.

The actuating elements 12 can be fabricated via sputtering or can simply be bought from commercially available sources in order to maybe save money and time.

Other than magnetic actuating elements, metal (Pt, Au) Janus particles for self-diffusiophoretic or -electrophoretic motion and gas filled bubbles with or without lipid membranes (for acoustic oscillation driven motion) can be used as actuating elements. Actuating elements can also be unicellular and multicellular biological organisms such as bacteria, microalgae, eukaryotic cells (spermatozoa, human cells, animal cells, single celled organisms), paramecium, volvox or the like.

In a further step, the (printed) elements 10, 12 of the micro-machines 8 are placed in a solution, for example a solution of a mixture of deionized water and a detergent. For example a solution comprising 0.1% Tween 20 solution (Sigma Aldrich, St Louis, Mo.) in deionized (DI) water can be used to prevent any non-specific aggregations. Mixing ratios can range between 0-5% (v/v) until the viscosity of the final solution starts affecting the motion of the actuators. Also, other non-ionic detergents, such as Triton® X-100, Tween® 80, MEGA 10, Nonidet® P-40 Substitute can be used for the same purpose as well.

Following the step of placing the elements 10, 12 in said solution, the mobile micro-machines 8 are assembled by applying an external electric field E, wherein said external electric field E forms electric field gradients at said one or more edges 11. Said gradients then cause an attraction of said actuating element 12 so that the main body 10 and the at least one actuating element 12 self-assemble into a micro-machine 8 at said one or more edges 11. This is achieved through the application of the electric field E with a field strength of the electric field lying in the range of 0 to 20V, preferably in the range of 0 to 10V. If bigger micro-machines 8 are to be assembled higher voltages will be needed, if smaller micro-machines 8 are assembled then lower voltages are sufficient.

Thus, through the designing of the exact shape of the main body 10, a body can be fabricated, at which specific electric field gradients are formed when the body is exposed to an external electric field. Since those gradients cause the actuating elements 12 to self-assemble at the respective edges 11 (or cavities 14) one does not have place each actuating element 12 separately in its respective place anymore. Once the elements 10, 12 are assembled, they will stick together as one micro-machine 8 and can be moved in specific direction by, for example, applying an external magnetic field to which the materials of which the actuating elements are fabricated (by coating or embedding respective materials) react.

In FIG. 2(a) one can see that several magnetic actuating elements 12 (10 μm diameter) can be attracted near a spherical non-magnetic main body 10 (60 μm diameter) towards regions with lower electric field strength E around the poles (see FIG. 2(b)). The bar indicates the normalized electric field strength (E/E₀)². FIG. 2(c) shows the assembled micro-machine 8, which is translated, i.e. moved, in a pre-definable direction via rolling of the micro-actuators 12 with a rotating magnetic field ω whose field strength and orientation define the direction of locomotion and the speed of the assembled micro-machine 8. The direction of the assembled micro-machine 8 can thus be steered by changing the applied magnetic field direction. The scale bar of FIG. 2(c) shows a size of 50 μm. The inset in FIG. 2(c) shows that the number of magnetic micro-actuators 12 assembled around the main body 10 can be tuned by controlled capture of the micro-actuators 12. FIGS. 2(d) and (e) show that the number of magnetic micro-actuators 12 assembled with a non-magnetic body 10 as well as the applied voltage (inset) determine the velocity of the assembled micro-machines 8. The scale bar, which is shown in FIG. 2(d), is 30 μm long. In FIG. 2(f) one can see that when a rotational magnetic field in the x-y plane is applied, the actuators 12 will rotate freely around the non-magnetic body 10 at low voltages. With increased voltage the actuators 12 mechanically couple to the non-magnetic body 10, which results in the rigid body rotation of the micro-machine 8.

FIGS. 3(a) and (b) show that a 3D “microcar” body 10 with four “wheel” pockets, i.e. cavities 14, can be designed to generate attractive DEP forces towards the underside of the wells. The bar indicates again the normalized electric field strength (E/E₀)². FIG. 2(c) shows how a directed assembly of the magnetic micro-actuators 12 into the wheel pockets 14 as the wheels is realized on-demand using DEP. In FIG. 3(d) one can see that an assembled “microcar” (assembled micro-machine) 8 is translated by vertically rotating magnetic fields and steered by changing the rotation axis of the magnetic field. In FIGS. 3(e) and (f) one can see how a micro-rotor body 10 with four fillets 14 is designed to generate attractive DEP forces giving rise to docking sites for the magnetic micro-actuators 12. FIG. 3(g) shows that on-demand assembly of a micro-rotor 8 is achieved with the applied electric field. In FIG. 3(h) it is shown that the micro-rotor body 10 and the magnetic microbeads 12 are coupled together with DEP and rotate rigidly when a horizontally rotating magnetic field in the x-y plane is applied. All scale bars, which are shown in these Figures, comprise a size of 25 μm.

FIG. 4(a) shows that Janus SiO₂ micro-particles with an Au cap can actively locomote based on self-dielectrophoresis (sDEP) at high frequencies and induced-charge electrophoresis (ICEP) at low frequencies. Locomotion direction is toward the Au cap in sDEP and reverses in ICEP. FIG. 4(b) shows that the Janus particle experiences a DEP force toward higher and lower electric field magnitudes at high and low frequencies, respectively. Thus, a microcar body 10 with hemicylindrical and filleted assembly sites 14 is designed to generate frequency tunable selective attraction of micro-actuators 12 (see FIG. 4(c) to (e)). Janus particles are attracted toward the equatorial line of hemicylinders at high frequencies and toward the filleted site at low frequencies. The bar indicates the normalized the electric field strength (E/E₀)². Propulsion of Janus particles assembled at the hemicylindrical sites results in rotation of the microcar body 10, whereas an assembly at the filleted site generates linear translation. FIGS. 4(f) and (g) show that an on-demand reconfiguration of locomotion mode is achieved by tuning the frequency and reorganizing the spatial layout of the assembly (scale bars at 25 μm).

FIGS. 5(a) to (c) show how a two-step hierarchical assembly takes place by (i) the assembly of micro-machine units 1 and 2, i.e. body parts 16, with self-propelled Janus particles and (ii) by the lateral assembly of unit 1 and unit 2 (body parts 16). Micro-machine units 16 are designed fora selective lateral assembly, where the undersides of ledges in the larger unit 2 generate low electric fields E that attract the smaller unit 1. The bar indicates again the normalized electric field strength (E/E₀)². FIGS. 5(d) and (e) show that a parallel assembly of mobile micro-machines 8 maintain the linear motion of the units 16, whereas anti-parallel assembly results in rotational motion (scale bars 25 μm).

FIGS. 6(a) and (b) show how serpentine columns are designed to generate attractive DEP forces along the roots of their helical threads. The bar indicates the normalized electric field strength (E/E₀)². In FIG. 6(c) one can see that a magnetic micro-actuator 12 climbs a column vertically mediated by DEP forces and magnetic rotation. The insets indicate the approximate location of the magnetic particle and the focal plane of the microscopy image at a given time point. FIG. 6(d) shows that the size selective vertical transportation of magnetic particles is achieved by tuning the pitch of helical threads. The pitch of helical threads determines an upper threshold for the particle size that can climb the column. The numbers on the columns indicate the pitch in micrometers and the particle sizes are shown above the images. In FIG. 6(e) one can see that a continuous up-and-down particle transportation in 3D under a constant rotational magnetic field is achieved by bridging two layers with serpentine columns of opposite handedness. Rotating micro-actuators 12 can be transported to a desired height for the assembly of micro-pumps 8 (see FIG. 6(f) while a constant rotation of the magnetic actuators around columns 10 generates a flow inside the microchannel. FIG. 6(g) shows how 3D flows are generated with an array of micro-pumps 8, assembled by vertical transportation of magnetic micro-particles 12 of different sizes to different heights over serpentine columns 10. The bar and vector fields indicate the mean flow velocity V measured by particle image velocimetry (scale bars 25 μm).

FIG. 7 shows simulated DEP forces on a spherical particle (10 μm diameter) under the electric field gradients generated by the fillet and cavity surface profiles, as shown in FIG. 1, for different feature dimensions (r=0-16 μm) and applied voltage (V). Attractive and repulsive interactions occur for F>0 and F<0, respectively.

In FIGS. 8(a) and (c) one can see a non-uniform electric field generated around a solid body (ε_{b}<εₘ) with (a) fillet and (c) cavity surface profiles as obtained by simulations. The bar indicates again the normalized electric field strength (E/E₀)². FIGS. 8(b) and (d) show that the DEP forces experienced by a spherical particle (εₚ<εₘ, 10 μm diameter) varies with the distance from the body for various feature dimensions r.

FIG. 9(a) shows how non-uniform electric fields generated around a spherical body (60 μm diameter) induce a DEP force on secondary spherical bodies that are touching. In FIG. 9(b) one can see that the DEP force varies from attraction to repulsion as the diameter of the secondary particle increases. The inset highlights the values of DEP force for particle diameters from 10 to 30 μm.

FIG. 10(a) shows an average distance between a central and satellite particles, while FIG. 10(b) shows that the average distance between particles decreases with the applied electric field strength. In FIG. 10(c) one can see fluorescent microscopy images for the characterization of the average distance. FIGS. 10(d) to (f) show induced dipolar interactions between a central and satellite particles near a conductive electrode. For example, the potential energy for dipolar interactions U_{DD} between a central and a satellite particle is calculated using Eq. 2, including the effects of image dipoles due to the presence of the conductive surface at z=0 (see FIG. 10(d)). (x, z) coordinates indicate the position of the satellite particle, whereas the central particle is positioned at (x=0, z=6). x and z coordinates are normalized to the radius of satellite particle (a₁). The bar indicates the magnitude of potential energy normalized to U₀. FIG. 10(e) shows the dipolar interaction force F=−∇U_{DD} where the vector arrows show the direction of F and the “color”, i.e. greyish, bar indicates the magnitude of F normalized to F₀. The dipolar force acting on the satellite particle positioned at z=1 (on top of the electrode) attracts the particle toward the substrate and the central particle (see FIG. 10(f)). U₀ and F₀ correspond to the maximum interactions that are observed for θ=0° when the two particles are at (head-to-toe) contact in the absence of the conductive substrate.

FIGS. 11(a) to (c) show the characterization of single particle velocities under applied electric fields. A lubrication theory estimation of the velocity of a particle rotating near a wall, where the particle velocity U increases with decreasing lubrication layer thickness h, is shown in FIG. 11(a). FIG. 11(b), on the other hand, shows the experimental measurement of the particle velocity under applied electric fields, where the velocity increases with applied peak-to-peak voltage Vₚₚ. A change in h as a function of Vₚₚ is estimated via the lubrication theory with Eq. 5 (see FIG. 11(c)). The curve represents the height variation modeled with Eq. 6. The error bars represent the standard deviation. Furthermore, a represents the particle radius, Ω the angular velocity, F_{P} the propulsive force and F_{D} the drag force. FIGS. 11(d) and (e) show the coupling between the central and the satellite particles in the translational micro-machine. A schematic of the coupling between the central particle (of radius a₂) and the satellite particle (of radius a₁) is shown in FIG. 11(d). The particles are firmly attracted together and to the electrode surface due to DEP interactions, which results in a thin lubrication layer between the particles and the substrate with thicknesses h₁ and h₂. A comparison of experimental trends with the model estimations for different values of friction coefficients μ_{f} is depicted in FIG. 11(e). In the Figures a represents the particle radius, Ω the angular velocity, U the velocity of the assembly, F_{P} the propulsive force, F_{D} the drag force, L the interfacial load and F_{f} the interfacial friction force. The coupling between the central and the satellite particle in the rotational joint is shown in FIGS. 11(f) and (g), where FIG. 11(f) depicts a schematic of the rotational coupling between the non-magnetic central particle (of radius a₂) and the magnetic satellite particle (of radius a₁). At low electric field strengths (Vₚₚ<6 V) the satellite moves freely around the central particle with angular velocity Ω₁, whereas the particles rotate as a rigid body with Ω₂ at an electric potential of above 6 V. FIG. 11(g) shows a comparison of experimental trends with the model estimations for the two regimes at varying electric potentials, whereas a is the particle radius, Ω the actuation angular velocity and h: lubrication layer thickness.

In FIGS. 12(a) and (b) one can see randomly dispersed non-magnetic objects with a 60 μm diameter (see FIG. 12(a)), which are captured with magnetic micro-actuators 12 (10 μm) via DEP and re-positioned by applying rotating magnetic fields (see FIG. 12(b)). Black and grey arrows show non-magnetic objects and micro-actuators 12, respectively. Pick-and-place manipulation is achieved by on-demand control of the electric field, thus, DEP attraction towards the non-magnetic objects.

In FIG. 13(a) one can see that Janus micro-particles are self-propelled with induced-charge electrophoresis (ICEP) with a SiO2 cap forward at low frequencies (f<25 kHz) and with self-dielectrophoresis (sDEP) with an Au cap forwards at high frequencies (f>25 kHz). FIG. 13(b) shows that the velocity is proportional to the square of the applied electric field magnitude in both ICEP and sDEP regimes. Error bars represent the standard deviation.

In FIGS. 14(a) and (b) one can see that a microstructure with a hemicylindrical site and a filleted site is designed to generate high and low electric fields, respectively, for frequency tunable selective attraction of micro-actuators 12. The white dashed circle represents the size of the Janus particle (8 μm diameter). The “color”, i.e. greyish, bar indicates again the normalized electric field strength (E/E₀)². FIGS. 14(c) and (d) show that Janus particles are attracted towards the equatorial line of the hemicylindrical site at high frequencies and towards the filleted site at low frequencies via DEP forces. The scale bars are in the range of 50 μm. Furthermore, one can see in FIGS. 14(e) and (f) that the orientation of assembled Janus particles showed ±10° angle difference with the hemicylindrical and filleted sites.

FIG. 15(a) shows that Janus SiO₂ micro-particles with an Au cap can actively locomote based on self-dielectrophoresis due to an asymmetric non-uniform electric field around the Janus particle near an electrode. Conductive Au caps of micro-particles experience a DEP force towards the higher field magnitude under a non-uniform electric field (FIG. 15(b)). A micro-rocket body 10 with two hemicylindrical docking stations 14 (10 μm diameter) is designed to generate selective attraction of Janus propellers 12 (see FIGS. 15(c) and (d)). Janus particles are attracted towards the equatorial line of hemicylinders with high electrical field strength via DEP forces. The “color”, i.e. greyish, bar indicates the normalized electric field strength (E/E₀)². Self-dielectrophoretic propulsion of Janus particles and directed assembly are realized on demand via DEP when the electric field is turned on (see FIG. 15(e)), whereas an assembled micro-rocket is propelled by the active Janus particle (FIG. 15(f)). The scale bars in the Figs. have a size of 25 μm. FIGS. 15(g) and (h) show how a micro-spinner body 10 with three hemicylindrical docking sites 14 (10 μm diameter) is designed to generate selective attraction of Janus propellers 12. Finally, FIG. 15(i) shows that self-dielectrophoretic propulsion and a directed assembly are realized on demand via DEP forces when the electric field is turned on. An assembled microspinner is for example rotated by three self-propelled Janus particles (FIG. 15(j), scale bars 40 μm).

In FIGS. 16(a) and (b) one can see a microcar body with a hemicylindrical and a filleted assembly site 14, which is designed to generate frequency-tunable selective attraction of micro-actuators 12. The Janus particle 12 is attracted to the equatorial line of the hemicylinder at high frequencies and to the filleted site at low frequencies. The “color”, i.e. greyish, bar indicates again the normalized electric field strength (E/E₀)². FIGS. 16(c) and (d) show that the propulsion of Janus particles assembled at the hemicylindrical site and the filleted site results in bidirectional linear translation of the microcar body 10, while FIGS. 16(e) and (f) show that a rotor body 10 with hemicylindrical and filleted sites arranged with 4-fold chiral symmetry is designed to generate frequency-tunable selective attraction of micro-actuators 12. Janus particles are attracted to the equatorial line of the hemicylinders at high frequencies and to the filleted sites at low frequencies. FIGS. 16(g) and (h) show that the propulsion of Janus particles assembled at the hemicylindrical and filleted sites results in bidirectional rotation of the rotor body (scale bars are 25 μm).

FIGS. 17(a) and (b) depict that micro-rotor bodies actuated with a total of eight micro-actuators 12 showed higher angular velocities compared to rotors actuated with four micro-actuators 12 (scale bar is 25 μm), while FIG. 17(c) shows that the angular velocity of the micro-rotor increases with electric field amplitude.

FIGS. 18(a) and (b) show that the anti-parallel assembly of mobile micro-machines 8 converts linear motion of individual units 16 into rotational motion, whereas a parallel assembly of units 16 maintains the linear motion (scale bars are 25 μm).

In FIG. 19 one can see that 3D flows are generated with an array of micro-pumps 8, assembled by vertical transportation of magnetic micro-particles 12 of different sizes to different heights (H) over serpentine columns 10. The flow velocity V varies with elevation from the substrate, visualized by the velocity fields obtained for different heights of the focal plane of the microscope. The “color”, i.e. greyish, bar and the vector fields indicate the mean flow velocity measured by particle image velocimetry. The pitch of column threads is indicated with the value on top of the columns in μm. The scale bars comprise again a size of 25 μm.

At last, in FIG. 20(a) a schematic of the electric field setup is shown, where micro-particles 12 are placed in a fluidic chamber which is formed by sandwiching a spacer between two planar ITO coated glass slides. An AC voltage source supplies the electric field inside the chamber. FIG. 20(b) shows an image of the custom five-coil magnetic field generating setup that houses the electric field chamber.

A detailed description of the invention is now first described by the example of different experiments that were conducted by using the method according to the invention to assemble the micro-machines assembled in the experiments:

The working principle of a shape-encoded assembly of micro-components under electric fields E relies on shape-dependent modulation of electric fields E around polarizable bodies 10 and resulting DEP forces experienced between different components of the micro-machine 8 assembly. Specifically, DEP forces act on polarizable bodies 10 placed under non-uniform electric fields represented by vector field E, along the direction of ∇|E|². For instance, a dielectric object with an absolute permittivity (ε_{b}) lower than that of the surrounding medium (εₘ) is negatively polarized and experiences a DEP force towards the lower field magnitudes under a non-uniform electric field (FIG. 1(a)). Complementarily, a polarizable body 10 modifies the electric field E around itself depending on its shape, generating local field gradients that other particles, e.g. the actuating elements 12, experience as DEP forces. Therefore, field gradients around the body can be programmed through shape, which drives the assembly of micro-machine parts at desired locations on the body via DEP interactions (FIG. 1(b)).

For programming local gradients, we need to understand how electric fields are modulated around different geometries. Here, the focus lies on lateral assemblies (in the x-y plane) of sedimented parts on a solid surface under vertically applied electric fields (in the z-axis). Additionally, the bodies used in experiments were being attracted to lower fields since they were made of insulating materials, which have a lower relative permittivity (ε_{b} ˜ 2-4) than the used solution (deionized water, εₘ=80). When certain profiles, such as fillets and cavities, were introduced on the side of a solid body in simulations, the electric field E weakened under the profile resulting in attractive DEP forces for components smaller than the height of the profile (FIG. 1c-f). As a general design principle, low electric fields are generated at regions that are shielded from the passage of electric fields, in this case under the profiles, since the main body 10 is less polarizable than the solution and deflects incident electric field lines. If the body is more polarizable, electric field lines tend to travel through the body and low and high electric field regions switch places. These interactions were further quantified using finite element analyses and it was found that fillet profiles with a radius smaller than the micro-component to be assembled would generate a repulsive DEP force (FIG. 1(g)). This is due to the formation of high electric field magnitudes at the upper sections of the fillet profile. In comparison, cavity profiles generate attractive DEP forces at the profile interface for almost all feature dimensions, which would lead to stable assemblies within the cavities (FIG. 1(g)). Exerted DEP forces are enhanced by increasing the applied electric field amplitude (as a function of E²) (FIG. 1(h), FIG. 7), whereas they diminish as the distance from the profile increases (FIG. 8).

To demonstrate controlled self-assembly of mobile micro-machines 8 under electric fields E, it was first focused on the assembly of a simple micro-vehicle 8 comprising a large non-magnetic dielectric spherical body 10 (60-μm diameter polyethylene particle) and multiple smaller magnetic micro-actuators 12 (10-μm diameter superparamagnetic polystyrene particles) organized around the larger body 10 (FIG. 2(a)). Upon application of an electric field E in the z-axis (6 Vₚₚ, E₀=2.8×10⁴ V/m, pp: peak-to-peak), the non-magnetic body generated local electric field gradients that attracted smaller micro-actuators 12 around its poles (FIG. 2(b), FIG. 9 and FIG. 10). Due to DEP forces sedimented magnetic micro-actuators 12 self-assembled around the lower pole and the number of magnetic micro-actuators 12 assembled around the body 10 was adjusted by the controlled capture of micro-particles (FIG. 2(c)). Assembled magnetic micro-actuators 12 served as propelling wheels upon application of a vertically rotating magnetic field and the micro-vehicle 8 was steered by changing the magnetic field direction (FIG. 2(c)). Furthermore, the velocity of the micro-vehicle 8 increased with the number of micro-actuators 12 (FIGS. 2(d) and (e)). However, the velocity of the micro-vehicle 8 was observed to decrease with increasing voltage, which was presumably due to increased mechanical coupling between the micro-particles and the substrate due to DEP interactions (FIG. 2(e), FIG. 10 and FIG. 11).

An on-demand and reversible assembly of magnetic micro-actuators with passive non-magnetic bodies was further used in pick-and-place manipulation of non-magnetic objects (FIG. 12).

Randomly distributed non-magnetic particles (FIG. 12(a)) were captured by magnetic micro-actuators 12 upon application of an electric field E, then translated to a new position by a rotating magnetic field and finally released when the electric field was turned off (FIG. 12(b)).

The strength of the attractive DEP forces between the passive body and micro-actuators can be further modulated via the applied electric field for tuning their mechanical coupling, enabling control over rotational degrees of freedom. At low voltages (<7 Vₚₚ, E₀<3.3×10⁴ V/m), small attractive DEP forces led to a loose lubrication coupling, which allowed micro-actuators 12 to move freely around the pole (FIG. 11). Therefore, when a horizontally rotating magnetic field was applied a free rotational joint was formed between the actuators 12 and the passive body 10 (FIG. 2(f)). However, when the voltage was increased above a certain threshold (>7 Vₚₚ, E₀>3.3×10⁴ V/m) the actuator particles 12 were mechanically locked to the passive body 10 due to increased particle-particle DEP interactions. Thus, the assembly rotated as a rigid body 8 under rotating magnetic fields (FIG. 2(f)). Moreover, it was noticed that below the rigid coupling threshold the angular velocity of micro-actuators 12 rotating freely around the body 10 increased with higher voltage (FIG. 2(f)).

Next, programmable self-assembly of mobile micro-machines 8 with shape-encoded physical interactions (FIG. 3) was realized. Micro-machine frames 10 with specific 3D geometries to generate electric field gradients that selectively attract micro-actuators 12 to desired locations on the micro-machine frame 10 were designed. Then, these 3D frames 10 were fabricated using two-photon lithography.

The first design was a microcar as a homage to the ubiquity of wheeled propulsion in our lives (which was also commemorated by earlier molecular machines). A microcar frame 10 with four-wheel pockets 14 was designed to generate attractive DEP forces to guide the assembly of magnetic micro-actuators 12 into these pockets 14 with low electric field strength (FIGS. 3(a) and (b)). On-demand self-assembly of micro-actuators 12 with the microcar frame 10 was achieved within seconds upon application of the electric field E (6 Vₚₚ, E₀=4.2×10⁴ V/m) (FIG. 3(c)). Enabled by free rotation of magnetic wheels inside their pockets 14 the microcar 8 was translated and steered by a vertically rotating magnetic field (FIG. 3(d)).

For building a rotary micro-machine 8 a micro-rotor frame 10 encompassing four docking sites 14 with fillet surface profiles to generate attractive DEP forces for assembly (FIG. 3(e) to (f)) was designed. When the electric field E was turned on, magnetic micro-actuators 12 self-assembled into the docking sites 14 within seconds (FIG. 3(g)). To ensure rigid coupling between the micro-rotor frame 10 and the magnetic micro-actuators 12 the electric field was set at a high value (10 Vₚₚ, E₀=7.1×10⁴ V/m). Therefore, upon application of a horizontally rotating magnetic field, the micro-rotor assembly 8 rotated as a rigid body (FIG. 3(h)).

The shape-encoded assembly process demonstrated here can be further utilized for building reconfigurable micro-machines 8 powered by self-propelled micro-motors 12. To demonstrate this, micro-machine frames 10 that can assemble with self-propelled Janus silica (SiO₂) micro-particles 12 with a gold (Au) cap (FIG. 4) were designed. Metallodielectric Janus micro-particles can actively propel themselves based on self-dielectrophoresis (sDEP) and induced-charge electrophoresis (ICEP), which both rely on asymmetric electric fields generated around the particle. sDEP occurs at high frequencies with the Janus particles travelling with their metallic cap forward, whereas the propulsion direction reverses in ICEP occurring at low frequencies (FIG. 4(a), FIG. 13). Due to the frequency-dependent asymmetric polarization of metallic and dielectric hemispheres, Janus particles are attracted to high electric fields at high frequencies with their metallic caps facing forward. Oppositely, at low frequencies Janus particles are attracted to low electric field regions with their silica sides facing forward (FIG. 4(b), FIG. 14).

Frequency-dependent self-propulsion and DEP response of Janus micro-particles 12 allow design of mobile micro-machines 8 with reconfigurable spatial organization and kinematics (FIG. 4, FIG. 15). Accordingly, microcar frame 10 with hemicylindrical and filleted sites that generate site-specific high and low electric fields, respectively, enabling frequency-tunable selective assembly of micro-actuators 12 (FIGS. 4(c) and (d)) were designed. Janus particles assembled at the hemicylindrical site above 25 kHz, which resulted in the rotation of the microcar 8 due to the off-centered push. At frequencies below 25 kHz Janus particles assembled at the filleted site, resulting in the linear translation of the microcar 8 due to the centered push (FIG. 4(e)). The microcar 8 was switched reversibly between rotation and translation modes on-demand by varying the frequency (FIGS. 4(f) and (g)). Different kinematic configurations were also programmed by changing the arrangement of the assembly sites (FIG. 16) and the micro-machine 8 velocity was controlled through the number of assembled propellers and the electric field strength (FIG. 17). It was also observed that assembled motors were perpetually replaced by incident propellers from the background, which demonstrated a form of self-repairing property.

Shape-encoded DEP interactions can be utilized to define physical interactions between mobile micro-machines 8, paving the way for hierarchical multi-machine assemblies. To prove the concept of multiscale hierarchical organization a two-level hierarchical assembly between constituent micro-machines (FIG. 5) was designed. In the first level self-propelled actuators 12 assemble with two microstructural units 10 (Units 1 and 2) to form mobile micro-machines 8, which translate linearly (FIG. 5(a) (i)). In the second level, Unit 2 assembles laterally with Unit 1 (FIG. 5(a) (ii)) through the low electric field generated underside of its ledges (FIGS. 5(b) and (c)). A parallel assembly preserved the linear translation of units (FIG. 5(d)), whereas an anti-parallel assembly resulted in a rotational motion (FIG. 5(e)). Micro-machine assemblies are extensible, where they can form three machine assemblies with an alternating sequence of Units 1 and 2 (FIG. 18).

The design principles introduced here can be accommodated to 3D micro-actuator manipulation and micro-machine assemblies. To show 3D manipulation of micro-particles, serpentine columns that can generate attractive DEP forces along the roots of their helical threads (FIGS. 6(a) and (b)) were designed. A magnetic micro-actuator 12 was transported vertically through the root of the helical thread 14 when rotated with an applied magnetic field (FIG. 6(c)). The pitch of helical threads controls the size of the low electric field regions generated along the root, which set an upper limit for the size of particles that can maintain attractive contact during surface climbing. An array of columns with varying pitches was designed and the size-selective vertical transportation of magnetic micro-actuators 12 (FIG. 6(d)) was demonstrated.

The ability to transport particles in 3D further enables bridging horizontal layers stacked at different heights. A particle rotating in the counter-clockwise direction ascends over a right-handed column and descends over a left-handed column, which enables it to travel seamlessly between top and bottom surfaces of a microchannel (FIG. 6(e)). The ability to transport particles vertically enables new strategies for building 3D micro-machines 8.

Micro-pumps were assembled by transporting magnetic micro-actuators 12 onto circular tracks on the columns 10, which are elevated at a desired height from the substrate. Constant rotation of the magnetic micro-particles 12 generated rotating flows centered around the columns 10, which was rectified into a linear pumping flow by placement of adjacent obstacles (FIG. 6(f)). Furthermore, it was possible to generate 3D flows using an array of micro-pumps assembled by magnetic particles of different sizes brought to different elevations over the columns (FIG. 6(g) and FIG. 19).

In the following the different results of the above conducted experiments are discussed:

Machines and robots at all scales rely on organization of multiple components that can direct mechanical energy and information from one to another to generate motion and function. In contrast to their counterparts at the molecular- and macro-scales current micro-machines are fabricated as monolithic units due to challenges in assembly of functional components at microscale, which limits their reconfigurability, integration with other systems and available intrinsic and extrinsic degrees of freedom. Modular self-assembly of micro-components with programmable spatial organization can enable a rich design space for development of mobile micro-machines with complex locomotion and advanced functionalities. For addressing the rational design of self-assembled micro-machines, assembly information needs to be spatially encoded into the building blocks, which can be in the form of physical interactions controlled by shape and material composition. In this study, a directed assembly process for building mobile micro-machines with programmable positional and directional configurations of motor sub-units of different actuation mechanisms around a 3D body is introduced.

Programmable self-assembly has generated considerable interest in colloidal science and active matter for its promise in rational design of complex micro/nanoscale structures and machines. In the scope of programmable self-assembly, assembly information can be encoded in the colloidal building blocks in several forms, such as surface chemistry (e.g., patchy colloids), particle shape (e.g., lock and key colloids) and DNA origami. Although these methods provide a rich and highly programmable design space for assembling complex structures, they have been mostly limited to static structures at thermodynamic equilibrium.

For the construction of colloidal machines that can process energy, motion and information the assembly of building blocks needs to be addressed along with their dynamical behavior. Recently, it has been shown that the shape can direct the dynamics of self-propelling agents under electric fields in a wide range of propulsion modalities and its relation to programmable self-assembly has been discussed, but the role of electric fields on the programmable self-assembly has been left as an open challenge.

In this study, this challenge is addressed by proposing shape-directed assembly of micro-machines from modular structural and motor sub-units. The fact that programmed DEP interactions depend on shape alone significantly facilitates encoding assembly information in building blocks without relying on multi-material composites and intricate surface chemistry modifications. Furthermore, most materials are electrically polarizable, which generalizes the applicability of the presented assembly methodology to synthetic as well as biological matter. Lastly, it is noteworthy to mention that the effective range (˜several body lengths of motor units) and magnitude of DEP forces allow for a highly rapid and efficient assembly, which was further enhanced by controlled guidance of magnetic actuators and active diffusion of self-propelled motors.

It was demonstrated that the organization and interactions of motor sub-units within the assembly direct the dynamics of the micro-machine covering translation and rotation with directed (magnetic steering) and autonomous (self-propelled) actuation. Programming positional and directional integration of motors can enable more complex micro-machine kinematics. Using frequency responsive Janus particles, it was showed that these assemblies can be reconfigured on the fly. Additionally, using the assembly approach presented here, it was possible to develop rotary joints via control over the rotational degrees of freedom between multiple components with tunable coupling. Rotary joints are particularly crucial in certain biological systems, and for development of synthetic molecular-/nano-/micro-machines due to their role in mechanical transmission of energy.

Introducing programmable hierarchies enriches the configurational landscape of the geometrical forms and kinematic modes of dynamic micro-machine assemblies. The intuitive design approach presented here was utilized for encoding multilevel assembly pathways demonstrating its capability for guiding the hierarchical assembly in a dynamic system. Shape-encoded assembly pathways can extend to 3D, which enabled the possibility to design topographical guides for 3D actuator manipulation and micro-machine assemblies. These capabilities can bring the vertical space within reach for lab-on-a-chip applications such as continuous transportation, sorting, digital manipulation of micro-objects and microfluidic flow generation as shown here.

Moreover, multiple modular components addressing different functions including sensing, cargo loading and actuation can be incorporated in the assembly in a programmable and reversible manner. For instance, drug-loaded passive bodies can be assembled with magnetic micro-actuators for in vitro targeted drug delivery and single cell manipulation applications such as for lab-on-a-chip studies, where uniform electric fields can be generated feasibly. However, applications without electric fields, e.g. in vivo biomedical applications, would require irreversible assembly of micro-components. This can be achieved by introducing bonding sites on micro-components during fabrication (e.g. by surface functionalization), which is followed by the assembly process under the electric field. Then, the assembled components can be transferred to an application-specific environment and actuated by non-electric means. Such irreversible assemblies would be especially useful in fabrication of biohybrid micro-robots, where spatial and directional configuration of the biological actuators is a critical determinant of the optimal performance. The method described here addresses programmable self-assembly at the microscale using shape and external fields and holds significant potential in development of multi-functional reconfigurable micro-machines and life-inspired complex hierarchical systems with applications in micro-robotics, colloidal science, medicine, and autonomous microsystems.

In the following the materials and methods used are described in more detail:

Designing Dielectrophoretic Interactions

COMSOL Multiphysics 5.2 Modeling Software (COMSOL, Inc.) was used to estimate modulation of electric field strength around dielectric bodies with different 3D shapes. While these simulations are semi-quantitative and do not take into account the electrical conductivity or the frequency dependency of the DEP response, they provide adequate information on the distribution of DEP forces in 3D as well as approximation of their direction, magnitude and sign. The simulations are then used to adjust the force profile near the dielectric surface in order to establish the desired actuator-body connection. Simulations were performed by solving the electrostatics equations for a given dielectric microstructure geometry (ε=4) placed in a rectangular microchannel containing deionized water as solution (εₘ=80). Top and bottom planes of the channel are modeled as electrodes, which are subjected to uniform potential (10 V, top electrode) and ground (0 V, bottom electrode) boundary conditions. Separation distance (H=50-75 μm) between the electrodes determines the uniform electric field magnitude inside the channel in the absence of micro-objects (E₀=ΔV/H). In all simulation figures “color” bars indicate the normalized electric field strength reported by (E/E₀)².

Micro-Actuators and the Fabrication of the Dielectric Body

Superparamagnetic polystyrene micro-particles with 10 μm diameter and embedded iron oxide nanoparticles (Sigma Aldrich, St Louis, Mo.) were used as magnetic actuators. Non-magnetic polyethylene microspheres of ˜60 μm diameter (Cospheric, Santa Barbara, Calif.) were used as the robot body in the velocity characterization experiments. For encoded assembly experiments, the dielectric bodies were 3D nanoprinted from IP-S photoresist on an indium-tin-oxide (ITO) coated glass using a commercial two-photon lithography system (Nanoscribe GmbH, Eggenstein-Leopolds-hafen, Germany). Self-propelled Janus micro-particles were fabricated by sputtering a 20 nm gold (Au) layer on a pre-dried self-assembled monolayer of spherical silica (SiO₂) particles of 7.82 μm diameter (Micro-particles GmbH, Germany) with a tabletop sputter coating system (Leica EM ACE600, Leica Microsystems GmbH, Germany). 3D micro-machine experiments were performed with ferromagnetic micro-particles of sizes varying between 4.67 to 33.7 μm (Spherotech, Inc., Lake Forest, Ill.). All experiments were performed in a 0.1% Tween 20 solution (Sigma Aldrich, St Louis, Mo.) in deionized (DI) water to prevent any non-specific aggregations.

Experimental Setup

A microchannel (50-75 μm height×6 mm width×10 mm length) composed of a transparent ITO-coated glass top piece encompassing an inlet and an outlet, a double-sided tape defining the channel shape and height, and an ITO-coated glass bottom piece was used to apply electric field (FIG. 20(a)). Double-sided tape was laser micro-machined (Epilog Laser, Scottsdale, Ariz.) to cut out the desired channel shape. The conductive ITO glasses surrounding the channel served as the parallel plate electrodes for applying alternating electric fields using an arbitrary wave generator (Tektronix AFG1022, Tektronix, Inc.). All experiments were done between 4 kHz and 1 MHz.

A custom five-coil magnetic guidance system was used to generate the magnetic fields that control the motion and the actuation behavior of the demonstrated micro-actuators (FIG. 20(b)). The coil setup was placed on an inverted optical microscope (Zeiss Axio Observer A1, Carl Zeiss, Oberkochen, Germany). The system was designed to establish magnetic field strengths up to 20 mT in x- and y-directions (aligned with the specimen plane) and up to 10 mT in the z-direction (out of plane). Each coil was controlled independently by a current controller (Escon 70/10, Maxon Motor AG) and current values were determined by pre-calculated field to current ratios. The experiments were performed in a workspace that lies in the center of the coil setup. Established magnetic fields were measured to be uniform within 5 mm from the center of the workspace.

Data Analysis

Acquired images were processed using Fiji to identify micro-robots and their positions. A tracking software was used to reconstruct trajectories of individual chains and their velocities. All quantitative values were presented as means±standard deviation of the mean (SD). All experiments were performed for at least three independent repeats. The fluid flow generated by 3D micro-machines was characterized through the use of particle image velocimetry (PIV). Polystyrene tracers of 500 nm diameter (Sigma Aldrich, St Louis, Mo.) were seeded into the microchannel medium for visualizing the flow. For processing the obtained images, we used the built-in functions in DynamicStudio 6.2 (Dantec Dynamics A/S, Skovlunde, Denmark) software.

1.-25. (canceled)

26. A method of assembling mobile micro-machines comprising a main body and at least one actuating element, wherein the method comprises the steps of:
defining a 2D or a 3D-shape of elements of the mobile micro-machines, the elements comprising components such as the main body and the at least one actuating element;
fabricating said elements, said step of fabrication comprising at least the fabrication of the main body, the main body comprising one or more edges;
providing a solution in which the micro-machine can be placed;
placing said fabricated main body of the mobile micro-machines into said solution;
providing the at least one actuating element in said solution; and
assembling said mobile micro-machines by applying an external electric field, wherein said external electric field forms electric field gradients at said one or more edges and wherein said gradients attract said actuating element so that the main body and the at least one actuating element self-assemble into a micro-machine at said one or more edges.

27. The method according to claim 26, wherein the main body comprises one or more body parts.

28. The method according to claim 26, wherein the main body is fabricated via 2D or 3D printing.

29. The method according to claim 26, wherein the main body comprises at least one cavity for at least one actuating element.

30. The method according to claim 29, wherein the at least one cavity forms a respective one or more of said one or more edges.

31. The method according to claim 26, wherein the actuating element is further configured as a sensing element and/or as a cargo carrying element.

32. The method according to claim 26, wherein the main body is fabricated of a resin, biological materials or drug loaded materials.

33. The method according to claim 26, wherein a shape of the actuating element is also defined during said step of defining a 3D-shape of elements of the micro-machines.

34. The method according to claim 33, wherein the actuating element is fabricated via 2D or 3D-printing during said step of fabricating said elements.

35. The method according to claim 26, wherein the actuating element comprises one of a spherical shape, a cylindrical shape, an oval shape, a rectangular shape, a square shape, a polygonal shape and a triangular shape.

36. The method according to claim 26, wherein the actuating element comprises magnetic particles.

37. The method according to claim 36, wherein the actuating element is at least partially coated with magnetic particles.

38. The method according to claim 36, wherein the particles have a size in the range of 0.01 to 1000 μm.

39. The method according to claim 26, wherein a field strength of the electric field lies in the range of 0.01 to 2*109 V/m.

40. The method according to claim 26, wherein the electric field comprises alternating electric fields between two plates.

41. The method according to claim 26, wherein the solution comprises deionized water.

42. The method according to claim 26, wherein the solution comprises a detergent.

43. The method according to claim 26, wherein the method further comprises the step of:
applying a magnetic field at the assembled micro-machines to move the at least one actuating element in a pre-defined direction in accordance with the magnetic field applied.

44. The method according to claim 26, wherein two or more actuating elements are provided, wherein the main body comprises one or more edges for each actuating element so that each actuating element assembles at the respective one or more edge associated with said actuating element.

45. The method according to claim 44, wherein said one or more edges for each actuating element form a respective cavity associated with said actuating element.

46. The method according to claim 26, wherein two or more actuating elements are provided for at least one of the cavities.

47. A mobile micro-machine comprising a main body and one or more actuating elements, each of said one or more actuating elements being arranged at one or more edges of said main body, said one or more actuating elements each having a size selected in the range of 0.01 to 250 μm and said main body having a height, width and/or length respectively selected in the range of 1 to 2000 μm.

48. The mobile micro-machine according to claim 47, wherein two or more actuating elements are arranged at said main body.

49. The mobile micromachine according to claim 47, wherein said one or more edges form a respective cavity at which said one or more actuating element.
